(19) United States
(12) Patent Application Publication
(10) Pub. No.: US 2025/0126684 A1
(43) Pub. Date: Apr. 17, 2025

(54) TRANSPARENT CONDUCTIVE FILM AND LIGHT CONTROL DEVICE

(71) Applicant: FUJIFILM Corporation, Tokyo (JP)

(72) Inventors: Takahiko ICHIKI, Kanagawa (JP); Hideki YASUDA, Kanagawa (JP); Kazuhiro HASEGAWA, Kanagawa (JP)

(73) Assignee: FUJIFILM Corporation, Tokyo (JP)

(21) Appl. No.: 18/988,786

(22) Filed: Dec. 19, 2024

Related U.S. Application Data
(63) Continuation of application No. PCT/JP2023/020585, filed on Jun. 2, 2023.

(30) Foreign Application Priority Data
Jun. 30, 2022 (JP) 2022-106111
Feb. 13, 2023 (JP) 2023-020115

(51) Int. Cl. H05B 3/86; G02F 1/1333; G02F 1/1345; G02F 1/163

(52) U.S. Cl. CPC H05B 3/86; G02F 1/133382; G02F 1/1345; G02F 1/163; H05B 2203/013

(57) ABSTRACT

A transparent conductive film includes a mesh-shaped portion that is formed of a plurality of conductive wirings, in which the mesh-shaped portion includes a plurality of non-conductive portions (22) that are trimmed by the continuous conductive wiring (21A), the non-conductive portion (22) includes a pair of extension portions (E1, E2) that extend along a pair of central axes (C1, C2) orthogonal to each other and have the same length, the pair of extension portions (E1, E2) intersect each other at an intersection (K) of the pair of central axes (C1, C2), each of the pair of extension portions (E1, E2) includes a projection portion (G1, G2) that projects in a direction intersecting an extension direction, and the non-conductive portion (22) has a shape that is symmetric with respect to each of the pair of central axes. (C1, C2).

### CROSS-REFERENCE TO RELATED APPLICATIONS

This application is a Continuation of PCT International Application No. PCT/JP2023/020585 filed on Jun. 2, 2023, which claims priority under 35 U.S.C. § 119 (a) to Japanese Patent Application No. 2022-106111 filed on Jun. 30, 2022 and Japanese Patent Application No. 2023-020115 filed on Feb. 13, 2023. The above applications are hereby expressly incorporated by reference, in their entirety, into the present application.

### BACKGROUND OF THE INVENTION

### 1. Field of the Invention

The present invention relates to a transparent conductive film and a light control device having transmittance with respect to an electromagnetic wave in a specific frequency band.

### 2. Description of the Related Art

In the related art, a sensor, a communication apparatus, or the like using an electromagnetic wave such as a millimeter wave or a microwave is generally used. This apparatus is mounted on, for example, an automobile, and a protective cover is provided around the apparatus in many cases. It is known that snow accretion or ice accretion on the cover or fogging or the like caused by water vapor causes erroneous detection in the sensor or communication failure in the communication apparatus disposed inside the cover. In order to remove snow accretion, ice accretion, and fogging, for example, a heat generating member disclosed in WO2017/163830A is developed. The heat generating member disclosed in WO2017/163830A includes: a three-dimensional structure with a plated layer; and a conductive laminate including a metal layer disposed on the plated layer, in which the metal layer functions as a heating wire.

In addition, it is known that an electromagnetic wave in a frequency band different from the frequency band of the electromagnetic wave that is transmitted and received by the sensor, the communication apparatus, or the like causes erroneous detection in the sensor and communication crosstalk or the like in the communication apparatus. In order to suppress erroneous detection in the sensor and communication crosstalk or the like, for example, a structure of a metal mesh disclosed in Vyachesla V. Komarov, Valery P. Meschanov, “Transmission properties of metal mesh filters at 90 GHz”, Journal of Computational Electronics, Feb. 28, 2019, 18:696-704 is known. In the metal mesh disclosed in Vyachesla V. Komarov, Valery P. Meschanov, “Transmission properties of metal mesh filters at 90 GHz”, Journal of Computational Electronics, Feb. 28, 2019, 18:696-704, a plurality of cross-shaped non-conductive portions arranged in a lattice form in two directions orthogonal to each other are formed. Due to the plurality of non-conductive portions, an electromagnetic wave in a frequency band corresponding to the size of the cross shape is likely to transmit the metal mesh, and an electromagnetic wave in the other frequency band is shielded.

### SUMMARY OF THE INVENTION

However, the heat generating member disclosed in WO2017/163830A cannot allow transmission of only an electromagnetic wave in a specific frequency band. Therefore, it is difficult to simultaneously achieve a heat generation function and a function of allowing transmission of only an electromagnetic wave in a specific frequency band.

In addition, the present inventors found that, in a case where the metal mesh disclosed in Vyachesla V. Komarov, Valery P. Meschanov, “Transmission properties of metal mesh filters at 90 GHz”, Journal of Computational Electronics, Feb. 28, 2019, 18:696-704 is energized to generate heat, a current intensively flows through the plurality of non-conductive portions such that local heat generation occurs and deterioration of the metal mesh such as oxidation of the metal mesh occurs in the local portion. In order to avoid the concentration of the current, a method of widening a gap between the plurality of non-conductive portions can be considered. However, in a case where the gap is widened, the transmittance of an electromagnetic wave having a specific frequency band corresponding to the size of the non-conductive portion decreases, and there is a problem in that the function of allowing transmission of only the electromagnetic wave in the specific frequency band is not sufficiently exhibited.

In addition, a light control device that is generally called light control glass, a light control film, or the like and where transparency changes during energization is known. For example, the light control device may be disposed as a partition plate of a room and switched to any one of a transparent state or an opaque state to be used for switching to any one of a state where one side of the light control device is easily visible from the other side of the light control device or a state where the visual recognition of the one side from the other side is suppressed. In order to allow an electromagnetic wave in a specific frequency band to transmit through the light control device, in a case where the metal mesh disclosed in Vyachesla V. Komarov, Valery P. Meschanov, “Transmission properties of metal mesh filters at 90 GHz”, Journal of Computational Electronics, Feb. 28, 2019, 18:696-704 is provided, even in a case where the light control device is in the opaque state by a plurality of slits in a lattice form formed by the plurality of non-conductive portions, the state of the one side may be visible from the other side of the light control device such that shielding properties decrease.

The present invention has been made in order to solve the above-described problems, and an object thereof is to provide: a transparent conductive film where local deterioration during heat generation can be suppressed while having a function of allowing transmission of only an electromagnetic wave in a specific frequency band and shielding properties can be improved in an opaque state of a light control device; and a light control device where shielding properties in an opaque state can be improved.

The above object can be achieved by the following configuration.
[1] A transparent conductive film for a heater, the transparent conductive film comprising:
   a substrate; and
   a mesh-shaped portion that is disposed on the substrate and is formed of a plurality of conductive wirings,
   in which the mesh-shaped portion includes a plurality of non-conductive portions that are arranged to form a regular repeating pattern and are trimmed by the continuous conductive wiring,
   the non-conductive portion includes a pair of extension portions that extend along a pair of central axes orthogonal to each other and have the same length,
   the pair of extension portions intersect each other at an intersection of the pair of central axes,
   each of the pair of extension portions includes a projection portion that projects in a direction intersecting an extension direction, and
   the non-conductive portion has a shape that is symmetric with respect to each of the pair of central axes.
[2] The transparent conductive film for a heater according to [1], in which a gap A between the non-conductive portions adjacent to each other and a radius B of a circumscribed circle of the non-conductive portion satisfy

(A/2)/B>0.2.
[3] The transparent conductive film for a heater according to [1] or [2],
   in which the repeating pattern is configured such that a plurality of square unit regions each of which surrounds the non-conductive portion centering on the intersection of the pair of central axes in the non-conductive portion are arranged in a direction along the pair of central axes, and
   a ratio of an area in which the non-conductive portion occupies the unit region is 25% or more and 50% or less.
[4] The transparent conductive film for a heater according to any one of [1] to [3], in which a conductive member is not present inside the continuous conductive wiring that trims the non-conductive portion.
[5] The transparent conductive film for a heater according to any one of [1] to [4], in which the projection portions adjacent to each other in the non-conductive portion are disposed at a gap.
[6] The transparent conductive film for a heater according to any one of [1] to [5], in which the continuous conductive wiring that trims the non-conductive portion consists of two kinds of linear portions parallel to the pair of central axes, respectively.
[7] A transparent conductive film for a light control device, the transparent conductive film comprising:
   a substrate; and
   a mesh-shaped portion that is disposed on the substrate and is formed of a plurality of conductive wirings,
   in which the mesh-shaped portion includes a plurality of non-conductive portions that are arranged to form a regular repeating pattern and are trimmed by the continuous conductive wiring,
   the non-conductive portion includes a pair of extension portions that extend along a pair of central axes orthogonal to each other and have the same length,
   the pair of extension portions intersect each other at an intersection of the pair of central axes,
   each of the pair of extension portions includes a projection portion that projects in a direction intersecting an extension direction, and
   the non-conductive portion has a shape that is symmetric with respect to each of the pair of central axes.
[8] A light control device comprising:
   a pair of the transparent conductive films for a light control device according to [7] that are disposed such that the mesh-shaped portions face each other; and
   a light control layer that is disposed between the pair of transparent conductive films for a light control device and where optical characteristics change depending on an electric signal.
[9] The light control device according to [8],
   in which the projection portions adjacent to each other in the non-conductive portion are disposed at a gap.
[10] The light control device according to [8] or [9],
   in which at least one non-conductive portion among the plurality of non-conductive portions in one transparent conductive film for a light control device among the pair of transparent conductive films for a light control device and the non-conductive portion in the other transparent conductive film for a light control device corresponding to the at least one non-conductive portion are disposed to be shifted from each other in a plan view, and
   a maximum amount of shift of the at least one non-conductive portion and the corresponding non-conductive portion in the plan view is 0.25 times or less a width of the extension portion.
[11] The light control device according to [8] or [9],
   in which a position of the intersection of the pair of central axes of the plurality of non-conductive portions in one transparent conductive film for a light control device among the pair of transparent conductive films for a light control device and a position of the intersection of the pair of central axes of the plurality of non-conductive portions in the other transparent conductive film for a light control device match with each other in a plan view.
[12] The light control device according to any one of [8] to [11],
   in which a conductive member is not present inside the continuous conductive wiring that trims the non-conductive portion.
[13] The light control device according to any one of [8] to [12],
   in which the continuous conductive wiring that trims the non-conductive portion consists of two kinds of linear portions parallel to the pair of central axes, respectively.
[14] The light control device according to any one of [8] to [13],
   in which the mesh-shaped portion includes a conductive transparent auxiliary conductive layer that is disposed in a region other than the non-conductive portion.

The light control device according to any one of [8] to [14], in which the light control layer is a liquid crystal layer or an electrochromic layer.

The transparent conductive film according to the present invention comprises: a substrate; and a mesh-shaped portion that is disposed on the substrate and is formed of a plurality of conductive wirings, in which the mesh-shaped portion includes a plurality of non-conductive portions that are arranged to form a regular repeating pattern and are trimmed by the continuous conductive wiring, the non-conductive portion includes a pair of extension portions that extend along a pair of central axes orthogonal to each other and have the same length, the pair of extension portions intersect each other at an intersection of the pair of central axes, each of the pair of extension portions includes a projection portion that projects in a direction intersecting an extension direction, and the non-conductive portion has a shape that is symmetric with respect to each of the pair of central axes. Therefore, local deterioration during heat generation can be suppressed while having a function of allowing transmission of only an electromagnetic wave in a specific frequency band, and shielding properties can be improved in an opaque state of a light control device.

### BRIEF DESCRIPTION OF THE DRAWINGS

FIG. 1 is a cross sectional view schematically showing a part of a transparent conductive film according to a first embodiment of the present invention.

FIG. 2 is a plan view showing the transparent conductive film according to the first embodiment of the present invention.

FIG. 3 is an enlarged schematic diagram showing a mesh-shaped portion according to the first embodiment of the present invention.

FIG. 4 is a diagram showing a non-conductive portion according to the first embodiment of the present invention.

FIG. 5 is a diagram showing a cross-shaped non-conductive portion.

FIG. 6 is a diagram showing a unit region according to the first embodiment of the present invention.

FIG. 7 is a diagram showing a non-conductive portion according to a first modification example of the first embodiment of the present invention.

FIG. 8 is a diagram showing a non-conductive portion according to a second modification example of the first embodiment of the present invention.

FIG. 9 is a diagram showing a non-conductive portion according to a third modification example of the first embodiment of the present invention.

FIG. 10 is a cross sectional view schematically showing a part of a light control device according to a second embodiment of the present invention.

FIG. 11 is a plan view showing a first conductive layer according to the second embodiment of the present invention.

FIG. 12 is a diagram showing the details of a cross sectional configuration of a first substrate and the first conductive layer according to the second embodiment of the present invention.

FIG. 13 is a diagram showing the details of a cross sectional configuration of the light control device according to the second embodiment of the present invention.

FIG. 14 is a diagram showing a maximum amount of shift between a non-conductive portion of the first conductive layer and a non-conductive portion of a second conductive layer according to the second embodiment of the present invention.

### DESCRIPTION OF THE PREFERRED EMBODIMENTS

Hereinafter, a transparent conductive film according to the present invention will be described in detail based on a preferred embodiment shown in the accompanying drawings.

The drawings described below are exemplary drawings for describing the present invention, and the present invention is not limited to the drawings described below.

In the following description, a numerical range indicated by the expression “to” includes numerical values described on both sides. For example, in a case where ε is a numerical value α to a numerical value β, the range ε is a range including the numerical value α and the numerical value β, which is expressed by a mathematical symbol α≤ε≤β.

Unless specified otherwise, the meaning of an angle such as “parallel” or “orthogonal” includes a case where an error range is generally allowable in the technical field.

In addition, the meaning of “the same” includes a case where an error range is generally allowable in the technical field.

In this specification, “(meth)acrylate” denotes either or both of acrylate and methacrylate, and “(meth)acryl” denotes either or both of acryl and methacryl. In addition, “(meth)acryloyl” denotes either or both of acryloyl and methacryloyl.

Unless specified otherwise, being transparent with respect to visible light represents that a visible light transmittance in a visible wavelength range of 380 nm to 800 nm is 40% or more, preferably 80.0% or more, and more preferably 90.0% or more. In the following description, unless specified otherwise, being transparent represents being transparent with respect to visible light.

The visible light transmittance is measured using “Plastics-Determination of Total Luminous Transmittance and Reflectance” defined by Japanese Industrial Standards (JIS) K 7375:2008.

### First Embodiment

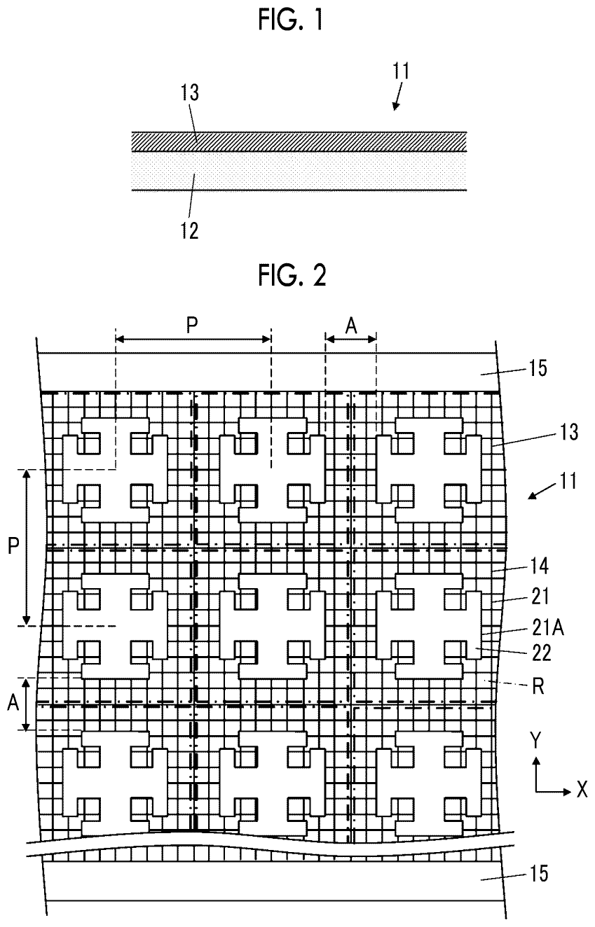

FIG. 1 shows a transparent conductive film 11 according to a first embodiment of the present invention. The transparent conductive film 11 according to the first embodiment can be used as a transparent conductive film for a heater that is energized to generate heat and has a function of a heater. The transparent conductive film 11 is a film-shaped member and includes an insulating transparent substrate 12 and a conductive layer 13 that is formed on a single surface of the substrate 12.

The conductive layer 13 has a visible light transmittance of, for example, 75.0% or more.

As shown in FIG. 2, the conductive layer 13 of the transparent conductive film 11 includes a mesh-shaped portion 14 that is formed of a plurality of conductive wirings 21 and a pair of electrode pads 15 that are connected to both ends of the mesh-shaped portion 14 to apply a voltage to the mesh-shaped portion 14. Each of the pair of electrode pads 15 has a rectangular shape, and the electrode pads 15 are disposed such that long sides thereof face each other. Here, for example, by applying a voltage to the pair of electrode pads 15 such that a current flows through the mesh-shaped portion 14, the mesh-shaped portion 14 can be heated. As a result, the transparent conductive film 11 functions as a so-called heater.

Hereinafter, for convenience of description, a direction from one electrode pad 15 toward another electrode pad 15 will be referred to as a Y direction, and a direction orthogonal to the Y direction will be referred to as an X direction.

The plurality of conductive wirings 21 forming the mesh-shaped portion 14 extend in the X direction and the Y direction.

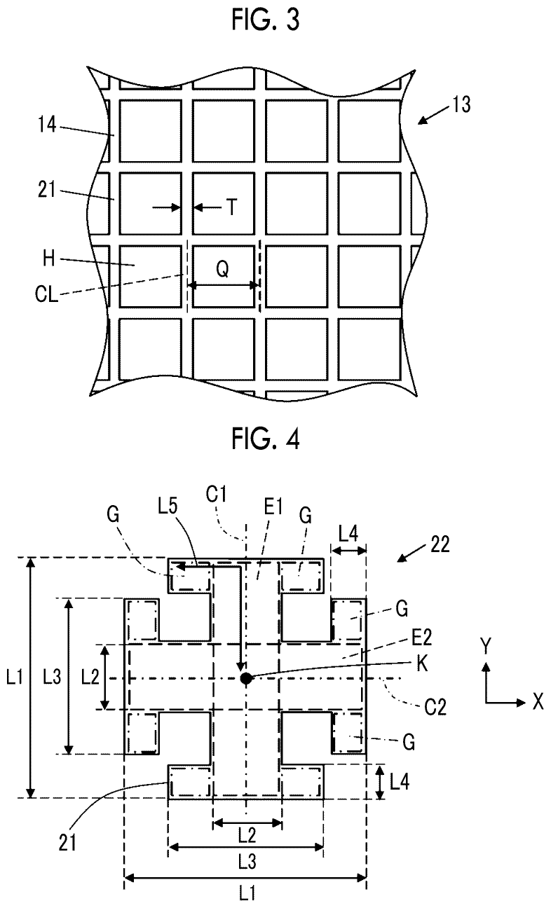

As shown in FIG. 3, the plurality of conductive wirings 21 have a line width T and are disposed at a pitch Q defined as a distance between center lines CL of the conductive wirings 21.

In addition, the mesh-shaped portion 14 includes a plurality of square opening portions H and forms a so-called square grid.

The line width T of the conductive wirings 21 is not particularly limited, and the upper limit thereof is preferably 1000.00 μm or less, more preferably 500.00 μm or less, and still more preferably 300.00 μm or less. The lower limit of the line width Tis preferably 1.00 μm or more and more preferably 3.00 μm or more. In a case where the line width T is in the above-described range, the mesh-shaped portion 14 can be made to have a high conductivity. In addition, from the viewpoint of conductivity, the thickness of the conductive wirings 21 can be set to be 0.01 μm or more and 200.00 μm or less, and the upper limit thereof is preferably 30.00 μm or less, more preferably 20.00 μm or less, still more preferably 9.00 μm or less, and still more preferably 5.00 μm or less. The lower limit of the thickness of the conductive wirings 21 is preferably 0.01 μm or more, more preferably 0.10 μm or more, and still more preferably 0.5 μm or more.

A sheet resistance of the conductive layer 13 formed of the plurality of conductive wirings 21 is preferably 0.1Ω/□ or more and 10.0Ω/□ or less and more preferably 0.3Ω/□ or more and 3.0Ω/□ or less. This way, the conductive layer 13 has a low sheet resistance of 10.0Ω/□ or less. Therefore, the conductive layer 13 has a high heater performance of generating a large amount of heat under a condition where a voltage is limited, and has a high electromagnetic wave transmittance. In addition, the conductive layer 13 has a resistance value of 0.10Ω/□ or more. Therefore, the conductive layer 13 has a high heater performance of generating a large amount of heat under a condition where a current is limited.

In addition, as shown in FIG. 2, the mesh-shaped portion 14 includes a plurality of non-conductive portions 22 that are arranged to form a regular repeating pattern and are trimmed by a continuous conductive wiring 21A. The plurality of non-conductive portions 22 are arranged in the X direction and the Y direction at a gap A and an arrangement pitch P.

Here, the gap A can be defined by the shortest distance in the X direction between the non-conductive portions 22 adjacent to each other in the X direction and the shortest distance in the Y direction between the non-conductive portions 22 adjacent to each other in the Y direction. In addition, the arrangement pitch P of the non-conductive portions 22 can be defined by a distance in the X direction between centers of the non-conductive portions 22 adjacent to each other in the X direction and a distance in the Y direction between centers of the non-conductive portions 22 adjacent to each other in the Y direction.

As shown in FIG. 4, the non-conductive portion 22 is trimmed by the continuous conductive wiring 21A, and a conductive member is not present inside the continuous conductive wiring 21A. Therefore, the inside of the non-conductive portion 22 is electrically insulated.

In addition, the non-conductive portion 22 includes a pair of extension portions E1 and E2 that extend along a pair of central axes C1 and C2 orthogonal to each other and have the same length L1 and width L2. In the example of FIG. 4, the central axis C1 extends along the Y direction, and the central axis C2 extends along the X direction. The pair of extension portions E1 and E2 intersect each other at an intersection K of the pair of central axes C1 and C2.

In addition, the extension portion E1 includes a projection portion G1 that projects in a direction intersecting the Y direction that is an extension direction, and the extension portion E2 includes a projection portion G2 that projects in a direction intersecting the X direction that is an extension direction. In the example of FIG. 4, the extension portion E1 includes the projection portion G1 that projects from both end parts in the Y direction to both sides in the X direction, respectively, and the extension portion E2 includes the projection portion G2 that projects from both end parts in the X direction to both sides in the Y direction, respectively.

This way, the extension portions E1 and E2 include the projection portions G1 and G2. Therefore, in portions where the projection portions G1 and G2 are positioned, each of the extension portions E1 and E2 has a width L3 wider than the width L2. In addition, the projection portion G1 has a width L4 in the Y direction, and the projection portion G2 has a width L4 in the X direction.

Here, the non-conductive portion 22 allows transmission of an electromagnetic wave in a specific frequency band corresponding to a length of an arm from the center that is the intersection K of the pair of central axes C1 and C2, that is, a length in the X direction or the Y direction from the intersection K to an end part of the projection portion G1 or G2. In FIG. 4, a length L5 of the arm of the non-conductive portion 22 can be substantially calculated from the sum of the distance from the intersection K of the pair of central axes C1 and C2 to the end part in the Y direction of the extension portion E1 and the length from the central axis C1 to the end part in the X direction of the projection portion G1, that is, the sum of half of the length L1 of the extension portion E1 and half of the width L3 of the extension portion E1 in the portion where the projection portion G1 is positioned. Therefore, depending on the frequency band of the electromagnetic wave that is desired to transmit through the non-conductive portion 22, the length L1 of the pair of extension portions E1 and E2 and the width L3 of the pair of extension portions E1 and E2 in the portions where the projection portions G1 and G2 are positioned are designed.

For example, in a case where an electromagnetic wave in a frequency band called a millimeter wave centering on 76.5 GHz transmits through the non-conductive portion 22, it is preferable that the length L1 is designed as 1.12 mm and the width L3 is designed as 0.72 mm. Note that the length L1 and the width L3 can be appropriately adjusted because they also depend on a positional relationship between the plurality of non-conductive portions 22. In addition, as the width L2 increases and as the thickness L4 increases, the amount of the electromagnetic wave transmitted through the non-conductive portion 22 can increase. Note that in a case where the values of the width L2 and the thickness L4 are certain values or more, the values may affect the length of the arm of the non-conductive portion 22. Therefore, it is desirable to appropriately adjust the values.

This way, the mesh-shaped portion 14 includes the non-conductive portion 22. Therefore, the mesh-shaped portion 14 allows transmission of an electromagnetic wave in a specific frequency band and shields an electromagnetic wave in the other frequency band.

In addition, the non-conductive portion 22 has a shape that is symmetric with respect to each of the pair of central axes C1 and C2. This way, the non-conductive portion 22 is symmetric with respect to the pair of central axes C1 and C2. As a result, the length L5 of the arm of the non-conductive portion 22 from the intersection K is uniform in four directions including the +X direction, the −X direction, the +Y direction, and the −Y direction, and the transmittance with respect to the electromagnetic wave in the specific frequency band can be improved, for example, as compared to a case where the non-conductive portion 22 is asymmetric with respect to the pair of central axes C1 and C2.

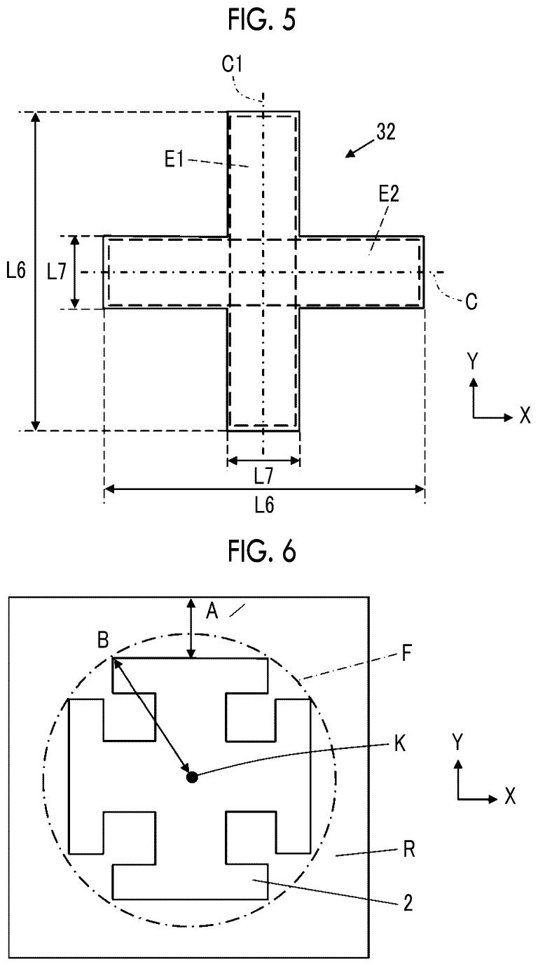

Incidentally, for example, as disclosed in Vyachesla V. Komarov, Valery P. Meschanov, “Transmission properties of metal mesh filters at 90 GHz”, Journal of Computational Electronics, Feb. 28, 2019, 18:696-704, a non-conductive portion 32 having a simple cross shape shown in FIG. 5 is known. The non-conductive portion 32 has a cross shape consisting of the pair of extension portions E1 and E2 that extend along the pair of central axes C1 and C2 orthogonal to each other. In the non-conductive portion 32, the pair of extension portions E1 and E2 have a length L6 and a width L7. The lengths of the pair of extension portions E1 and E2 are designed depending on the frequency band of the electromagnetic wave that is desired to transmit through the non-conductive portion 32.

For example, in a case where a millimeter wave centering on 76.5 GHz transmits through the non-conductive portion 32, it is preferable that the length L6 is designed as 1.33 mm.

This way, in a case where the non-conductive portion 22 according to the first embodiment of the present invention is compared to, for example, the non-conductive portion 32 having the simple cross shape shown in FIG. 5, the dimensions of the non-conductive portion 22 in the X direction and the Y direction can be reduced while maintaining the length of the arm corresponding to the electromagnetic wave in the frequency band that is desired to transmit.

Here, in a case where a regular repeating pattern is formed by arranging the non-conductive portions 32 having the cross shape shown in FIG. 5 in the X direction and the Y direction on a mesh-shaped portion consisting of a plurality of conductive wirings, the gap between the non-conductive portion 32 is short. Therefore, in a case where a voltage is applied to the mesh-shaped portion, a current intensively flows through the non-conductive portion 32 such that deterioration of the conductive wirings, for example, oxidation of the conductive wirings between the non-conductive portions 32 at a high temperature may occur.

In the non-conductive portion 22 according to the first embodiment of the present invention, the dimensions in the X direction and the Y direction can be reduced while maintaining the length of the arm corresponding to the electromagnetic wave in the frequency band that is desired to transmit. Therefore, while simultaneously achieving a heat generation function and a function of allowing transmission of an electromagnetic wave in a specific frequency band, the gap A between the non-conductive portions 22 can be widened, and local deterioration can be suppressed.

Here, as shown in FIG. 6, it is preferable that the gap between the non-conductive portions 22 and a radius B of a circumscribed circle F of the non-conductive portion 22 satisfy

(A/2)/B>0.2

from the viewpoint of widening the gap between the non-conductive portions 22 to further suppress the current concentration between the non-conductive portions 22.

In addition, as shown in FIG. 6, a square unit region R that surrounds the non-conductive portion 22 centering on the intersection K of the pair of central axes C1 and C2 is set. The regular repeating pattern formed on the mesh-shaped portion 14 is configured such that the unit regions R are arranged in the X direction and the Y direction as shown in FIG. 2.

Here, in order to allow a sufficient amount of an electromagnetic wave to transmit through the non-conductive portion 22, it is preferable that a ratio of an area in which the non-conductive portion 22 occupies the unit region R is 25% or more. In addition, in order to widen the gap A between the non-conductive portions 22 adjacent to each other to suppress local concentration of a current, it is preferable that the ratio of the area in which the non-conductive portion 22 occupies the unit region R is 50% or less. Accordingly, in order to suppress local concentration of a current while allowing a sufficient amount of an electromagnetic wave to transmit the non-conductive portion 22, it is preferable that the ratio of the area in which the non-conductive portion 22 occupies the unit region R is 25% or more and 50% or less.

In addition, the conductive member is not present inside the continuous conductive wiring 21A that trims the non-conductive portion 22. Therefore, the electromagnetic wave in the specific frequency band that is desired to transmit is not reflected from the conductive member, and the non-conductive portion 22 can have excellent transmittance with respect to the electromagnetic wave in the specific frequency band. In the example of FIG. 4, air is present inside the continuous conductive wiring 21A that trims the non-conductive portion 22. However, the continuous conductive wiring 21A can also be filled with an insulating member (not shown). Even in this case, the non-conductive portion 22 can have excellent transmittance with respect to the electromagnetic wave in the specific frequency band.

In addition, in a case where the projection portions G1 and G2 adjacent to each other in the non-conductive portion 22 are designed to be in contact with or coupled with each other, the transmittance of the electromagnetic wave in the frequency band that is desired to transmit decreases due to the shape of the non-conductive portion 22. Therefore, it is preferable that the projection portions G1 and G2 adjacent to each other in the non-conductive portion 22 are disposed at a gap.

In addition, the continuous conductive wiring 21A that trims the non-conductive portion 22 is the same as the other plurality of conductive wirings 21 forming the mesh-shaped portion 14, and it is preferable that the continuous conductive wiring 21A consists of two kinds of linear portions parallel to each of the pair of central axes C1 and C2, respectively, that is, a linear portion along the X direction and a linear portion along the Y direction and does not include portions inclined in the X direction and the Y direction. In this case, all the conductive wirings 21 including the continuous conductive wiring 21A that trims the non-conductive portion 22 extend along the X direction and the Y direction. Therefore, in a case where an observer verifies the mesh-shaped portion 14, the presence of the non-conductive portion 22 is not particularly conspicuous.

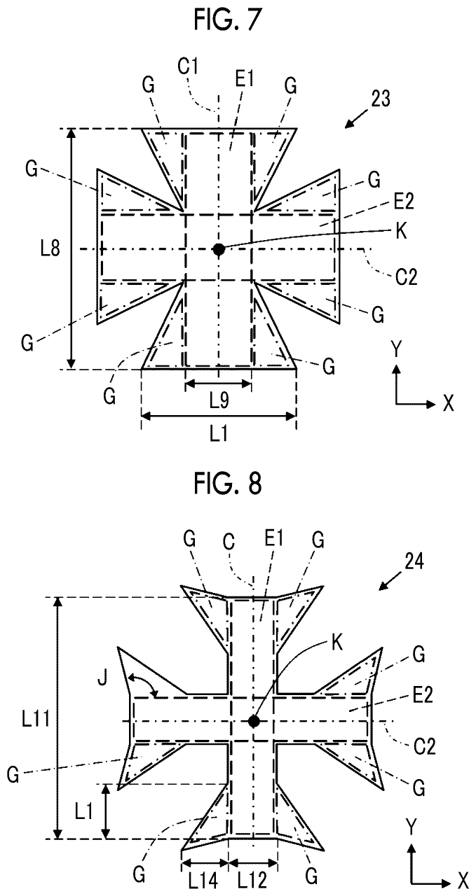

In addition, the shape of the projection portions G1 and G2 in the non-conductive portion 22 is not limited to a rectangular shape shown in FIG. 4 and can have any shape. The projection portions G1 and G2 can also have, for example, a right triangular shape as shown in FIG. 7. In a non-conductive portion 23 shown in FIG. 7, the pair of extension portions E1 and E2 have a length L8 and a width L9, and have a maximum width L10 in the portions where the projection portions G1 and G2 are positioned. Even in this case, while ensuring the length of the arm for allowing an electromagnetic wave in a desired frequency band to transmit through the non-conductive portion 23, the dimensions of the non-conductive portion 23 in the X direction and the Y direction can be reduced.

The projection portions G1 and G2 can also have, for example, an obtuse triangular shape as shown in FIG. 8. In a non-conductive portion 24 shown in FIG. 8, the pair of extension portions E1 and E2 have a length L11 and a width L12. The projection portion G1 is positioned at a tip part of the extension portion E1, and projects in a direction inclined with respect to the extension direction of the extension portion E1, that is, the Y direction. In addition, the projection portion G1 has a length L13 in the Y direction and a length L14 in the X direction. The projection portion G2 is positioned at a tip part of the extension portion E2, and projects in a direction inclined with respect to the extension direction of the extension portion E2, that is, the X direction. In addition, the projection portion G2 has a length L13 in the Y direction and a length L14 in the X direction although not shown in the drawing. In addition, an obtuse angle is formed by an interior angle between vertices in contact with the tip sides of the pair of extension portions E1 and E2 among three interior angles of the obtuse triangle formed by the projection portions G1 and G2. As a result, the projection portion G1 projects in the Y direction beyond the tip of the extension portion E1, and the projection portion G2 projects in the X direction beyond the tip of the extension portion E2.

This way, even in a case where the non-conductive portion 24 includes the projection portions G1 and G2 of the obtuse triangle, while ensuring the length of the arm for allowing an electromagnetic wave in a desired frequency band to transmit through the non-conductive portion 24, the dimensions of the non-conductive portion 24 in the X direction and the Y direction can be reduced.

In addition, as long as the projection portions G1 and G2 are disposed at a gap without contact with each other, the projection portions G1 and G2 do not need to be disposed at the tip parts of the pair of extension portions E1 and E2 as shown in FIG. 4, and can be disposed at any positions such as the center portions of the pair of extension portions E1 and E2 in the extension direction.

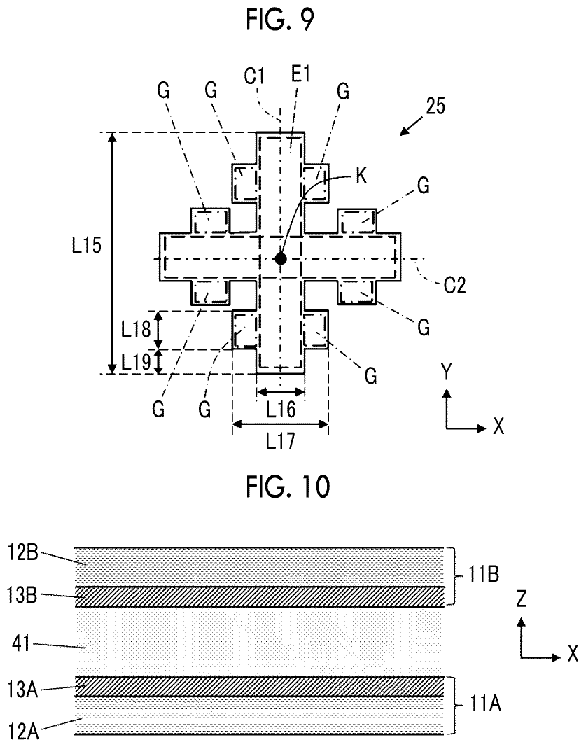

The projection portions G1 and G2 can also be disposed, for example, on the intersection K side of the central axes C1 and C2 further than the end parts of the pair of extension portions E1 and E2 as shown in FIG. 9. In a non-conductive portion 25 shown in FIG. 9, the pair of extension portions E1 and E2 have a length L15 and a width L16, and have a width L17 in the portions where the projection portions G1 and G2 are positioned. The projection portion G1 has a thickness L18 in the Y direction. In addition, the extension portion E1 has a length L19 from the tip to the projection portion G1 in the Y direction. In addition, the projection portion G2 has a thickness L18 in the X direction although not shown in the drawing. The extension portion E2 has a length L19 from the tip to the projection portion G2 in the X direction.

This way, even in a case where the projection portions G1 and G2 are disposed at positions other than the tips of the pair of extension portions E1 and E2, the dimensions of the non-conductive portion 25 in the X direction and the Y direction can be reduced while maintaining the length of the arm corresponding to the electromagnetic wave in the frequency band that is desired to transmit. Therefore, while simultaneously achieving a heat generation function and a function of allowing transmission of an electromagnetic wave in a specific frequency band, the gap A between the non-conductive portions 25 can be widened, and local deterioration can be suppressed.

In addition, FIG. 1 shows that the conductive layer 13 has a shape along a plane. However, the conductive layer 13 can also have a shape along a curved surface. For example, by forming the conductive layer 13 on the substrate 12 having a curved surface, the conductive layer 13 can be formed to have a shape along the curved surface shape of the substrate 12. Examples of the curved surface shape include a shape along a surface of any three-dimensional shape such as a sphere, a cylinder, or a cone.

In addition, the conductive layer 13 can also have a shape along a more complicated three-dimensional surface. Examples of the complicated three-dimensional shape include an emblem of an automobile, a radome of a radar, a front cover of a radar, a headlamp cover of an automobile, an antenna, and a reflector. By disposing the transparent conductive film 11 according to the first embodiment of the present invention along the three-dimensional shape, for example, the transparent conductive film 11 can be disposed along an emblem of an automobile, and a radar can be mounted in the emblem.

In addition, in a case where the design of a member covered with the transparent conductive film 11 is desired to be visible to an external observer, for example, in a case where the transparent conductive film 11 is disposed along an emblem of an automobile, it is desirable that the transparent conductive film 11 has transparency. In this case, in order to make the presence of the mesh-shaped portion 14 inconspicuous, the upper limit of the pitch Q of the mesh-shaped portion 14 is preferably 800.00 μm or less, more preferably 600.00 μm or less, and still more preferably 400.00 μm or less. In addition, the lower limit of the pitch Q is preferably 5.00 μm or more, more preferably 30.00 μm or more, and still more preferably 80.00 μm or more.

In addition, in order for the transparent conductive film 11 to have a visible light transmittance of 75.0% or more, an opening ratio of the mesh-shaped portion 14 is preferably 75% or more and more preferably 80% or more. Here, the opening ratio of the mesh-shaped portion 14 refers to the ratio of transmitting portions excluding the conductive wirings 21 to the region of the mesh-shaped portion 14. That is, the opening ratio corresponds to a ratio of the total area of the plurality of opening portions H to the total area of the mesh-shaped portion 14.

The shape of the plurality of opening portions H in the mesh-shaped portion 14 is not limited to a square shape. For example, a triangle such as a regular triangle, an isosceles triangle, or a right triangle, a quadrangle such as a square, a rectangle, a parallelogram, or a trapezoid, a regular polygon such as a (regular) hexagon or a (regular) octagon, a circle, an ellipse, a star shape, or a geometric figure as a combination of the above-described shapes can also be adopted.

### Second Embodiment

The use of the transparent conductive film 11 according to the first embodiment as a heater has been described. However, the use of the transparent conductive film 11 is not limited to a heater. In addition, by being included in a light control device that is called light control glass, a light control film, or the like and where transparency changes during energization, the transparent conductive film 11 can also be used as a transparent conductive film for a light control device that allows transmission of only an electromagnetic wave in a specific frequency band.

FIG. 10 shows a light control device according to the second embodiment. The light control device includes a first substrate 12A, a first conductive layer 13A that is formed on the first substrate 12A, a second substrate 12B, a second conductive layer 13B that is formed on the second substrate 12B, a light control layer 41 that is disposed to be interposed between the first conductive layer 13A and the second conductive layer 13B. A first transparent conductive film 11A is formed of the first substrate 12A and the first conductive layer 13A, and a second transparent conductive film 11B is formed of the second substrate 12B and the second conductive layer 13B. In addition, although not shown in the drawing, the light control device includes an electrode for energizing the light control layer 41.

The first substrate 12A and the second substrate 12B are the same as the substrate 12 according to the first embodiment.

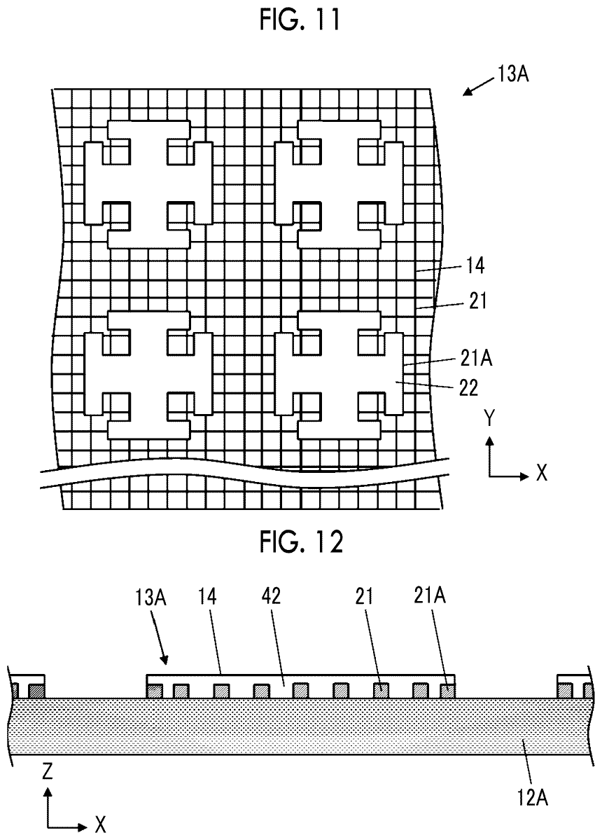

The first conductive layer 13A includes the mesh-shaped portion 14 according to the first embodiment as shown in FIG. 11. The mesh-shaped portion 14 is formed of the plurality of conductive wirings 21 and 21A, and includes the non-conductive portion 22 that is trimmed by the conductive wiring 21A. In addition, as shown in FIG. 12, the mesh-shaped portion 14 includes a transparent auxiliary conductive layer 42 that is formed on and between the plurality of conductive wirings 21 and 21A other than the non-conductive portions 22.

The transparent auxiliary conductive layer 42 does not need to be formed but is preferably formed because it has a function of shielding electromagnetic waves other than the electromagnetic wave in the specific frequency band corresponding to the non-conductive portions 22 by uniformly operating the light control layer 41 without any time difference. As the transparent auxiliary conductive layer 42, a transparent conductive polymer film such as poly(3,4-ethylenedioxythiophene) polystyrene sulfonate (PEDOT-PSS), polyaniline, polypyrrole, polythiophene, or polyisothianaphthene, or a dispersive conductive film consisting of a polymer film or the like where a transparent conductive inorganic oxide such as indium tin oxide (ITO) or conductive fine particles are dispersed can be used. Representative examples of the conductive fine particles include carbon nanotubes, metal nanowires, and conductive metal oxide.

The transparent auxiliary conductive layer 42 can be obtained by uniform adhesion and film formation using a method such as coating, printing, or a vacuum process. As the method of coating and printing, a coater such as a slide coater, a slot die coater, a curtain coater, a roll coater, a bar coater, a gravure coater or an existing method such as an ink jet printing method or a screen printing method can be used. As the method of the vacuum process, an existing method such as a vacuum deposition method or a sputtering method can be used. The transparent auxiliary conductive layer 42 can also have a monolayer structure or a laminated structure of a plurality of layers. In FIG. 12, the transparent auxiliary conductive layer 42 is formed on and between the plurality of conductive wirings 21 and 21A. The transparent auxiliary conductive layer 42 may be formed such that the heights of the plurality of conductive wirings 21 and 21A and the transparent auxiliary conductive layer 42 from the first substrate 12A are the same. In addition, in order to prevent the transparent auxiliary conductive layer 42 from being formed on the non-conductive portions 22, an existing patterning method such as a photolithography method, an ink jet printing method, or a screen printing method can be used.

As the conductive fine particles, fine elongated particles such as carbon nanotubes or metal nanowires are preferable because they exhibit high conductivity with a small amount. It is more preferable that the content of the conductive fine particles is small because high transparency can be maintained. The thickness of the conductive fine particles is preferably 1 nm to 100 nm. The thickness is more preferably 70 nm or less because the particles are substantially invisible. The thickness is more preferably 5 nm or more because electric resistance further decreases such that electrical conductivity can be easily obtained. The thickness is still more preferably 10 nm to 50 nm. An aspect ratio of the conductive fine particles is preferably 10 or more and 100000 or less, and the lower limit value is more preferably 30 or more and most preferably 100 or more. As the carbon nanotubes, multi-walled carbon nanotubes (MWNT), double-walled carbon nanotubes (DWNT), or single-walled carbon nanotubes (SWNT) are known. As the metal nanowires, silver nanowires, metal nanowires, copper nanowires, or the like are known.

It is preferable that the conductive fine particles in the dispersive transparent conductive film are dispersed in a polymer matrix. Even in a case where amount of the conductive fine particles is small, necessary conductivity can be obtained as long as the conductive fine particles are uniformly dispersed. A polymer that can be used in the dispersive transparent conductive film is not particularly limited as long as the polymer can be dissolved in a solvent to disperse the conductive fine particles without aggregation. Specific examples of the polymer include a polyamide resin, a polyester resin, a polyolefin resin, a polycarbonate resin, a polyvinyl alcohol resin, a polysulfone resin, a cellulose ester resin, a cellulose ether resin, a vinyl resin such as polyvinyl chloride, polyvinylidene fluoride, polybutadiene, or polystyrene, a polyacrylic ester resin, and a polymethacrylic resin. In addition, the conductive fine particles may be dispersed and applied to a monomer or an oligomer such as an epoxy resin, a thermosetting polyester resin, or an acrylic ester and polymerized with heat or light. In addition, a method of dispersing the conductive fine particles in a water-dispersed polymer latex liquid, applying and drying the dispersion, and applying heat at a glass transition temperature or higher of the polymer to form a film can also be used.

In order to uniformly operate the light control layer 41, the transparent auxiliary conductive layer 42 has preferably a thickness of 0.2 μm to 50.0 μm, more preferably a thickness of 0.5 μm to 30.0 μm in consideration of a high corrosion prevention function and process suitability, and still more preferably a thickness of 1.0 to 15.0 μm. The concentration of the conductive fine particles in the dispersive transparent conductive film is preferably 0.01 to 1.00 wt %. The concentration is more preferably in a range of 0.04% to 0.40% and most preferably in a range of 0.08% to 0.25%. The amount of the conductive fine particles in the dispersive transparent conductive film is preferably 0.05 to 1000.00 mg/m². As the amount of the conductive fine particles increases, the conductivity is improved, but the light transmittance decreases. The amount of the conductive fine particles is more preferably 0.50 to 300.00 mg/m² and still more preferably 4.00 to 100.00 mg/m².

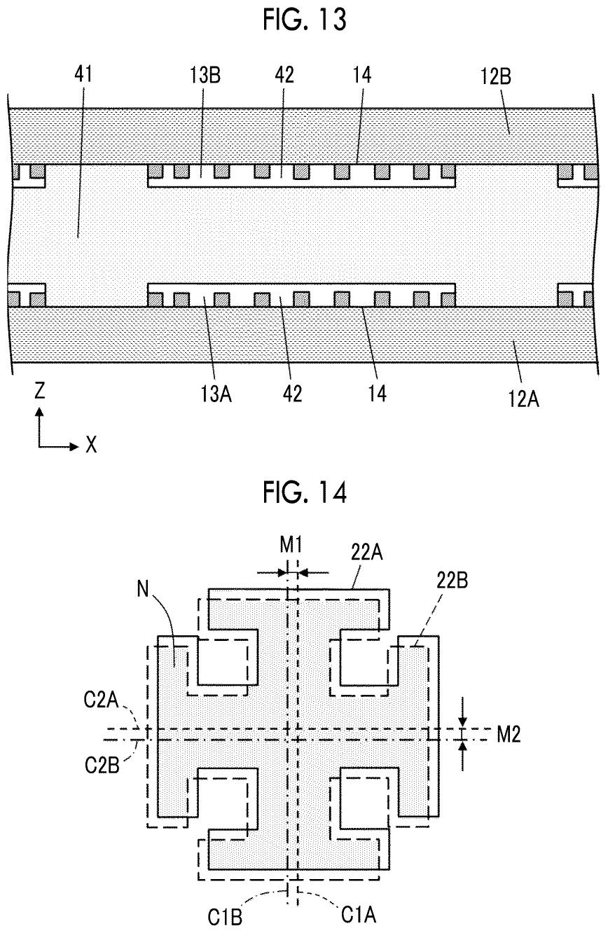

As in the first conductive layer 13A, the second conductive layer 13B is formed of the plurality of conductive wirings 21 and 21A, and includes the mesh-shaped portion 14 including the plurality of non-conductive portions 22 that are trimmed by the conductive wiring 21A. In addition, as shown in FIG. 13, as in the mesh-shaped portion 14 of the first conductive layer 13A, the mesh-shaped portion 14 of the second conductive layer 13B includes the transparent auxiliary conductive layer 42 that is formed on and between the plurality of conductive wirings 21 and 21A other than the non-conductive portions 22.

The light control layer 41 is a layer where optical characteristics such as transparency, that is, transmittance of visible light change depending on an electric signal. The light control layer 41 can include a so-called liquid crystal layer or a so-called electrochromic layer. Here, the electrochromic layer can enter an opaque state by changing the color from a colorless transparent color to a dark color such as black under the control of an energized state. Therefore, an electrochromic layer where the color bleeds out to the non-conductive portions 22 in the opaque state such that shielding properties increase is more preferable.

The electrochromic layer is a layer formed of an electrochromic material. The electrochromic material is not particularly limited as long as it is a compound having electrochromicity, and may be any one of an inorganic compound, an organic compound, or a mixed-valence complex. Examples of the inorganic compound include Mo₂O₃, Ir₂O₃, NiO, V₂O₅, WO₃, and TiO₂. Examples of the organic compound include a polypyrrole compound, a polythiophene compound, a polyparaphenylene vinylene compound, a polyaniline compound, a polyacetylene compound, a polyethylene dioxythiophene compound, a metal phthalocyanine compound, a viologen compound, a viologen salt compound, a ferrocene compound, a dimethyl terephthalate compound, and a diethyl terephthalate compound. Examples of the mixed-valence complex include a Prussian blue type complex (KFe[Fe(CN)₅]).

The electrochromic layer can be formed using a well-known method, and may be formed in a vacuum by sputtering method, or may be formed by applying a diluted solution of the electrochromic material.

The light control layer 41 including the electrochromic layer is configured by disposing the electrochromic layer between the pair of transparent conductive layers. In the electrochromic layer, by applying a voltage between the transparent conductive layers, for example, a transmittance in a specific wavelength range changes, the state changes from a transparent state to an opaque state, or the tone changes. In addition, an electrolyte layer or the like may be provided between the transparent conductive layer and the electrochromic layer.

The liquid crystal layer is a layer including liquid crystal, and examples thereof include a layer that is filled with liquid crystal using a spacer or the like and sealed. The liquid crystal may be any type, may be a TN type, or may be a STN type. In addition, the liquid crystal layer may be formed of a polymer dispersed liquid crystal (PDLC). Examples of the PDLC include network liquid crystal where a network structure is formed of a polymer in the liquid crystal layer. In addition, the liquid crystal may be a microencapsulated liquid crystal (PDMLC) where liquid crystal is microencapsulated and dispersed in a binder resin. Examples of the binder resin used in the PDMLC include a polyvinyl acetal resin such as a polyvinyl butyral resin.

The light control layer 41 including the liquid crystal layer forms a liquid crystal cell by disposing the liquid crystal layer between the pair of transparent conductive layers. In addition, depending on the type of the liquid crystal, an alignment film or the like may be provided between the conductive layer and the liquid crystal layer. For example, the liquid crystal layer may be in any of a normal mode where the liquid crystal layer is transparent in a case where a voltage is applied between the transparent conductive layer or a reverse mode where the liquid crystal layer is opaque in a case where a voltage is applied between the transparent conductive layer, but is preferably in the reverse mode from the viewpoint of power consumption because a period of time where the liquid crystal layer is transparent is long for use in a window or the like.

By controlling the energized state of the light control layer 41, the light control layer 41 can be switched to any one of the transparent state or the opaque state to be switched to any one of a state where one side of the light control device is easily visible from the other side or a state where the visual recognition of the one side from the other side is suppressed. For example, in a case where the light control device is used as a partition plate, the above-described switching of the state may be used, for example, by hiding the one side of the light control device from the other side to protect the privacy of the one side.

For example, in a case where the first conductive layer 13A and the second conductive layer 13B of the light control device include the plurality of non-conductive portions 32 having the simple cross shape shown in FIG. 5, the light control device can allow transmission of only the electromagnetic wave in the specific frequency band corresponding to the plurality of non-conductive portions 32. Even in a case where the light control layer 41 is in the opaque state by a plurality of slits in a lattice form formed by the plurality of non-conductive portions 32, the state of one side of the light control device is visible from the other side, and there is a case where shielding properties cannot be sufficiently ensured.

In the light control device according to the embodiment of the present invention, for example, as shown in FIG. 4, the plurality of non-conductive portions 22 include the projection portions G1 and G2. Therefore, the dimensions of the non-conductive portions 22 in the X direction and the Y direction can be reduced, and the formation of the plurality of slits in a lattice form can be prevented. As a result, in a case where the light control layer 41 is in the opaque state, the visual recognition of the state of the one side of the light control device from the other side is suppressed, and sufficient shielding properties can be ensured.

As long as the light control device can allow transmission of the electromagnetic wave in the specific frequency band, the non-conductive portions 22 of the first conductive layer 13A and the non-conductive portions 22 of the second conductive layer 13B corresponding to each other can also be disposed to be shifted from each other in a plan view as shown in FIG. 14. This amount of shift can be defined by, for example, a maximum value of a gap M1 in the X direction between a central axis CA along the Y direction of a non-conductive portion 22A of the first conductive layer 13A and a central axis C1B along the Y direction of a non-conductive portion 22B of the second conductive layer 13B, and a gap M2 in the Y direction between a central axis C2A along the X direction of the non-conductive portion 22A and a central axis C2B along the X direction of the non-conductive portion 22B. Hereinafter, this amount of shift will be referred to as the maximum amount of shift.

Here, the electromagnetic wave in the specific frequency band transmits through a region N where the non-conductive portion 22A of the first conductive layer 13A and the non-conductive portion 22B of the second conductive layer 13B overlap each other. Therefore, as the maximum amount of shift decreases, the shape of the region N approaches the non-conductive portions 22A and 22B and selectively allows transmission of the electromagnetic wave in the specific frequency band. In addition, as the maximum amount of shift increases, the shape of the region N moves away from the non-conductive portions 22A and 22B and selectively suppresses transmission of the electromagnetic wave in the specific frequency band. In order to sufficiently allow only the electromagnetic wave in specific frequency band to transmit through the light control device, it is preferable that the maximum amount of shift is 0.25 times or less the width of the pair of extension portions E1 and E2 of the non-conductive portions 22A and 22B. In particular, in the non-conductive portions 22A and 22B including the projection portions G1 and G2, in a case where the maximum amount of shift exceeds 0.25 times, the width of the extension portions E1 and E2 decreases such that the amount of the electromagnetic wave transmitted decreases, and the dimensions of the projection portions G1 and G2 of the extension portions E1 and E2 decrease such that the peak wavelength of the electromagnetic wave to be transmitted changes. Due to the synergistic effect of these factors, the transmission of the electromagnetic wave in the specific frequency band is rapidly selectively suppressed.

In order to allow the electromagnetic wave in the specific frequency band to transmit through the light control device, in a case where the light control device is seen in a plan view, that is, seen from a Z direction perpendicular to an XY plane, it is preferable that a position of the intersection K of the pair of central axes C1 and C2 of the plurality of non-conductive portions 22 of the first conductive layer 13A and a position of the intersection K of the pair of central axes C1 and C2 of the plurality of non-conductive portions 22 of the second conductive layer 13B match with each other.

Hereinafter, each of the members forming the transparent conductive film 11 according to the first embodiment will be described in detail. Each of the members forming the light control device according to the second embodiment other than the light control layer 41 is based on the description of each of the members of the transparent conductive film 11 according to the first embodiment.

### <Substrate>

The substrate 12 is not particularly limited as long as it has insulating properties and can support at least the conductive layer 13. However, it is preferable that the substrate 12 is transparent and is formed of a resin material.

Specific examples of the resin material forming the substrate 12 include polymethyl methacrylate (PMMA), acrylonitrile butadiene styrene (ABS), polyethylene terephthalate (PET), polycarbonate (PC), polycycloolefin, (meth)acryl, polyethylene naphthalate (PEN), polyethylene (PE), polypropylene (PP), polystyrene (PS), polyvinyl chloride (PVC), polyvinylidene chloride (PVDC), polyvinylidene difluoride (PVDF), polyarylate (PAR), polyethersulfone (PES), polymer acryl, a fluorene derivative, a crystalline cycloolefin polymer (COP), and triacetyl cellulose (TAC).

Here, from the viewpoints of the transparency and the durability of the substrate 12, it is preferable that the substrate 12 includes, as a major component, any one of a polymethyl methacrylate resin, a polycarbonate resin, an acrylonitrile/butadiene/styrene resin, or a polyethylene terephthalate resin. Here, the major component of the substrate 12 refers to a component of which the content is 80% or more with respect to the components of the substrate 12.

The visible light transmittance of the substrate 12 is preferably 85.0% to 100.0%.

In addition, the thickness of the substrate 12 is not particularly limited, and from the viewpoint of handleability or the like, is preferably 0.05 mm or more and 2.00 mm or less and more preferably 0.10 mm or more and 1.00 mm or less.

### <Primer Layer>

In order to strongly support a conductive layer 13, a primer layer may be provided between the substrate 12 and the conductive layer 13. The material of the primer layer is not limited as long as the conductive layer 13 can be strongly supported. In a case where the conductive layer 13 is formed of the plurality of conductive wirings 21, it is particularly preferable that the primer layer is formed of a urethane-based resin material.

### <Conductive Wiring>

The conductive wiring 21 is formed of a conductive material. As the conductive wiring 21, a metal, a metal oxide, a carbon material, a conductive polymer, or the like can be used. For example, in a case where the conductive wiring 21 is formed of a metal, the kind of the metal is not particularly limited, and examples thereof include copper, silver, aluminum, chromium, lead, nickel, gold, tin, and zinc. From the viewpoint of conductivity, copper, silver, aluminum, or gold is preferable. Examples of a method forming the metallic conductive wiring 21 include a semi-additive method a fully additive method, a subtractive method, a silver halide method, printing of a metal-containing ink or a precursor thereof, an ink jet method, or a laser direct structuring method can be used, and a combination of the above methods can also be used. As the metal, a bulk material can be used, and nanowires or nanoparticles can also be used. In a case where the conductive wiring 21 is formed of a carbon material, the structure or the composition thereof as the conductive wiring 21 is not particularly limited, and carbon nanotubes, fullerene, carbon nanobuds, graphene, graphite, or the like can be used. In a case where the conductive wiring 21 is formed of a metal oxide, ITO can be used as the conductive wiring 21. In a case where the conductive wiring 21 is formed of a conductive polymer, PEDOT/PSS or the like can be used as the conductive wiring 21.

### EXAMPLES

The present invention will be described in more detail based on the following examples. Materials, used amounts, ratios, treatment details, treatment procedures, and the like shown in the following examples can be appropriately changed within a range not departing from the scope of the present invention. Accordingly, the scope of the present invention is not limited to the following examples.

### Example 1

### (Preparation of Substrate)

A roll-shaped polycarbonate resin film (UV244, manufactured by Covestro AG) having a thickness of 250.0 μm was prepared as a substrate.

(Preparation of Composition for Forming Primer Layer) The following components were mixed to obtain a composition for forming a primer layer.

| | |
|---|---|
| Z913-3 (manufactured by Aica Kogyo Co., Ltd.) | 33 parts by mass |
| IPA (isopropyl alcohol) | 67 parts by mass |

### (Formation of Primer Layer)

The obtained composition for forming a primer layer was applied using a bar coating method to the substrate such that an average dry film thickness was 4.0 μm, and was dried at 80° C. for 1 minute. Next, the formed layer of the composition for forming a primer layer was irradiated with light and cured using a metal halide ultraviolet (UV) lamp at an exposure amount of 0.5 J/cm² to form a primer layer.

### (Preparation of Composition for Forming Plated Layer Precursor Layer)

The following components were mixed to obtain a composition for forming a plated layer precursor layer.

| | |
|---|---|
| IPA (isopropyl alcohol | 38.00 parts by mass |
| Polybutadiene maleic acid | 4.00 parts by mass |
| FOM-03008 (manufactured by Fujifilm | 1.00 part by mass |
| Wako Pure Chemical Corporation) | |
| IRGACURE OXE02 (manufactured by | 0.05 parts by mass |
| BASF SE, ClogP = 6.55) | |

FOM-03008 includes a compound represented by the following formula as a major component.

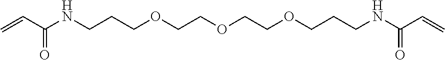 [SMILES: C=CC(=O)NCCCOCCOCCOCCCNC(=O)C=C]

(Preparation of Substrate with Plated Layer Precursor Layer)

The obtained composition for forming a plated layer precursor layer was applied using a bar coating method to the primer layer such that the film thickness was 0.2 μm, and was dried in an atmosphere of 120° C. for 1 minute. Next, by bonding a polypropylene film having a thickness of 12.0 μm to the composition for forming a plated layer precursor layer, a substrate with the plated layer precursor layer was prepared.

(Preparation of Substrate with Plated Layer)

A quartz glass film mask on which an exposure pattern corresponding to the mesh-shaped portion 14 and the pair of electrode pads 15 shown in FIG. 2 was formed was prepared. In this film mask, the exposure pattern corresponding to the mesh-shaped portion 14 has a pattern corresponding to the plurality of non-conductive portions 22 shown in FIG. 4. The film mask was attached to the plated layer precursor layer side of the substrate with the plated layer precursor layer, and UV irradiation (energy amount: 200 mJ/cm², wavelength: 365 nm) was performed through the film mask. Next, the exposed substrate with the plated layer precursor layer was developed by pure showering for 5 minutes. As a result, the substrate with the patterned plated layer was prepared.

### (Formation of Conductive Film)

The substrate with the plated layer was dipped in a 1 mass % sodium bicarbonate aqueous solution at 35° C. for 5 minutes. Next, the substrate with the plated layer was dipped in a palladium catalyst-added solution RONAMERSE SMT (manufactured by Rohm and Haas Electronic Materials LLC) at 55° C. for 5 minutes. The substrate with the plated layer was cleaned with water, was dipped in CIRCUPOSIT 6540 (manufactured by Rohm and Haas Electronic Materials LLC) at 35° C. for 5 minutes, and subsequently was cleaned with water again. Further, the substrate with the plated layer was dipped in CIRCUPOSIT 4500 (manufactured by Rohm and Haas Electronic Materials LLC) at 45° C. for 20 minutes and was cleaned with water to form a conductive film on the plated layer. As a result, a transparent conductive film according to Example 1 where a copper conductive layer including the mesh-shaped portion 14 and the pair of electrode pads 15 shown in FIG. 2 was provided on the substrate was obtained.

In the transparent conductive film according to Example 1, the unit region R was a square region having a side length of 1.68 mm, and the area thereof was 2.82 mm². In addition, in the non-conductive portion, the length L1 of the pair of extension portions was 1.12 mm, and the width L2 thereof was 0.33 mm. In the pair of extension portions, the width L3 of the portion where the projection portion was positioned was 0.72 mm, and the thickness L4 of the projection portion was 0.16 mm. The area of the non-conductive portion was 0.88 mm², and the ratio of the area where the non-conductive portion occupied the unit region R was 31%. In addition, the gap A between the non-conductive portions adjacent to each other in the X direction and the Y direction was 0.56 mm, the radius B of the circumscribed circle of the non-conductive portion was 0.66 mm, and (A/2) B was 0.42.

### Example 2

A transparent conductive film according to Example 2 was prepared using the same method as that of Example 1, except that a film mask having an exposure pattern corresponding to the non-conductive portions 23 having the shape shown in FIG. 7 was used instead of the non-conductive portions 22 having the shape shown in FIG. 4 in the film mask used in Example 1. In addition, in the non-conductive portion, the length L8 of the pair of extension portions was 1.20 mm, and the width L9 thereof was 0.20 mm. In the pair of extension portions, the maximum width L10 of the portion where the projection portion was positioned was 0.55 mm. The area of the non-conductive portion was 0.79 mm², and the ratio of the area where the non-conductive portion occupied the unit region R was 28%. In addition, the gap A between the non-conductive portions adjacent to each other in the X direction and the Y direction was 0.56 mm, the radius B of the circumscribed circle of the non-conductive portion was 0.66 mm, and (A/2) B was 0.42.

### Example 3

A transparent conductive film according to Example 3 was prepared using the same method as that of Example 1, except that a film mask having an exposure pattern corresponding to the non-conductive portions 24 having the shape shown in FIG. 8 was used instead of the non-conductive portions 22 having the shape shown in FIG. 4 in the film mask used in Example 1. In addition, in the non-conductive portion, the length L8 of the pair of extension portions was 1.20 mm, and the width L9 thereof was 0.15 mm. In addition, in the projection portion, a width L13 along the extension direction of the extension portion was 0.30 mm, a width L14 of the extension portion along the width direction orthogonal to the extension direction was 0.10 mm, and an interior angle J forming an obtuse angle was 120°. The area of the non-conductive portion was 0.56 mm², and the ratio of the area where the non-conductive portion occupied the unit region R was 20%. In addition, the gap A between the non-conductive portions adjacent to each other in the X direction and the Y direction was 0.37 mm, the radius B of the circumscribed circle of the non-conductive portion was 0.68 mm, and (A/2) B was 0.27.

### Example 4

A transparent conductive film according to Example 4 was prepared using the same method as that of Example 1, except that a film mask having an exposure pattern corresponding to the non-conductive portions 25 having the shape shown in FIG. 9 was used instead of the non-conductive portions 22 having the shape shown in FIG. 4 in the film mask used in Example 1. In addition, in the non-conductive portion, the length L15 of the pair of extension portions was 1.12 mm, and the width L16 thereof was 0.33 mm. In the pair of extension portions, the width L17 of the portion where the projection portion was positioned was 0.72 mm. In addition, the thickness L18 of the projection portion was 0.16 mm, and the length L19 from the tip of the extension portion to the projection portion in the extension direction was 0.04 mm. The area of the non-conductive portion was 0.88 mm², and the ratio of the area where the non-conductive portion occupied the unit region R was 31%. In addition, the gap A between the non-conductive portions adjacent to each other in the X direction and the Y direction was 0.56 mm, the radius B of the circumscribed circle of the non-conductive portion was 0.63 mm, and (A/2) B was 0.44.

### Comparative Example 1

A transparent conductive film according to Comparative Example 1 was prepared using the same method as that of Example 1, except that a film mask having an exposure pattern corresponding to the non-conductive portions 32 having the cross shape shown in FIG. 5 was used instead of the non-conductive portions 22 having the shape shown in FIG. 4 in the film mask used in Example 1. In addition, in the non-conductive portion, the length L15 of the pair of extension portions was 1.40 mm, and the width L16 thereof was 0.28 mm. The area of the non-conductive portion was 0.71 mm², and the ratio of the area where the non-conductive portion occupied the unit region R was 25%. In addition, the gap A between the non-conductive portions adjacent to each other in the X direction and the Y direction was 0.48 mm, the radius B of the circumscribed circle of the non-conductive portion was 0.705 mm, and (A/2) B was 0.34.

### Example 5

Using the same manufacturing method as that of the transparent conductive film according to Example 1, a mesh-shaped portion was formed on a first substrate. Next, using a photolithography method, a PEDOT/PSS (manufactured by Aldrich) having a thickness of 300 nm was applied to cover only a portion of the mesh-shaped portion on the first substrate and cured at 130° C. for 7 minutes to form a transparent auxiliary conductive layer. Next, a tungsten oxide (WO₃) thin film having a thickness of 300 nm was formed on the transparent auxiliary conductive layer to obtain a first transparent conductive film with a reactive sputtering method in an oxygen atmosphere using a RF magnetron sputtering device. Likewise, instead of the WO₃ thin film, a nickel oxyhydroxide (NiOOH) thin film having a thickness of 300 nm was formed to obtain a second transparent conductive film with a reactive sputtering method in a water vapor atmosphere using a RF magnetron sputtering device. Next, in a state where the first transparent conductive film and the second transparent conductive film were disposed to face each other such that the WO₃ thin film and the NiOOH thin film faced each other, a polyethylene microporous film having a thickness of 5 μm was impregnated with an electrolyte solution where lithium trifluoromethanesulfonate as an electrolyte was dissolved in polyethylene glycol monoether to obtain an electrolyte film, the electrolyte film was pressure-bonded, and a peripheral part of the substrate was sealed to obtain a light control device.

In the light control device according to Example 5, in a case where the positions of the plurality of non-conductive portions in the first transparent conductive film and the positions of the plurality of non-conductive portions in the second transparent conductive film were observed using an optical microscope, the position of the intersection K of the pair of central axes C1 and C2 of the plurality of non-conductive portions in the first transparent conductive film and the position of the intersection K of the pair of central axes C1 and C2 of the plurality of non-conductive portions in the second transparent conductive film matched with each other in a plan view. That is, the maximum amount of shift of the pair of central axes C1 and C2 of the non-conductive portions in the first transparent conductive film and the pair of central axes C1 and C2 of the non-conductive portions in the second transparent conductive film was 0.000 mm. In order to obtain the maximum amount of shift, the gap M1 between one central axis C1 of the non-conductive portion in the first transparent conductive film and one central axis C1 of the non-conductive portions in the second transparent conductive film and the gap M2 between another central axis C1 of the non-conductive portion in the first transparent conductive film and another central axis C1 of the non-conductive portions in the second transparent conductive film were measured using an optical microscope.

### Example 6

A light control device was prepared using the same method as that of Example 5, except that the non-conductive portions in the first transparent conductive film and the non-conductive portions in the second transparent conductive film were disposed to be shifted from each other in a plan view. In Example 6, the maximum amount of shift of the pair of central axes C1 and C2 of the non-conductive portions in the first transparent conductive film and the pair of central axes C1 and C2 of the non-conductive portions in the second transparent conductive film was 0.066 mm. Therefore, a ratio of the width of the extension portion to the maximum amount of shift was 0.20.

### Example 7

A light control device was prepared using the same method as that of Example 5, except that the non-conductive portions in the first transparent conductive film and the non-conductive portions in the second transparent conductive film were disposed to be further shifted from each other in a plan view. In Example 7, the maximum amount of shift of the pair of central axes C1 and C2 of the non-conductive portions in the first transparent conductive film and the pair of central axes C1 and C2 of the non-conductive portions in the second transparent conductive film was 0.092 mm. Therefore, a ratio of the width of the extension portion to the maximum amount of shift was 0.28.

### Example 8

Using the same manufacturing method as that of the transparent conductive film according to Example 1, a mesh-shaped portion was formed on a first substrate. Next, using a photolithography method, a PEDOT/PSS (manufactured by Aldrich) having a thickness of 300 nm was applied to cover only a portion of the mesh-shaped portion on the first substrate and cured at 130° C. for 7 minutes to form a transparent auxiliary conductive layer. Next, polyimide (manufactured by JSR Corporation, Optomer AL1254) was applied with a thickness of 100 nm, was heated at 90° C. for 10 minutes, and was calcined at 120° C. for 90 minutes. The calcined polyimide film was uniaxially rubbed to form an alignment film, and a first transparent conductive film was obtained.

Using the same method as the method of forming the first transparent conductive film, a second transparent conductive film was obtained. Next, 95 parts of a liquid crystal compound (manufactured by HCCH, 854600-100) and 5 parts of a crosslinked liquid crystal monomer (manufactured by BASF SE, LC242) were mixed. 0.95 parts of a polymerization initiator (manufactured by BASF SE, IRGACURE TPO) was added to the obtained mixture, was heated to an isotropic phase, and was stirred to obtain a liquid crystal composition. The obtained liquid crystal composition was applied to a surface of the alignment film of the first transparent conductive film such that the thickness was 10 μm, and a coating layer was formed. Next, the alignment film of the second transparent conductive film was bonded to come into contact with the coating layer, was heated at 90° C. for 1 minute, and was irradiated with light having a central wavelength of 365 nm from a LED light source to prepare a light control device according to Example 8. In Example 8, the position of the intersection K of the pair of central axes C1 and C2 of the plurality of non-conductive portions in the first transparent conductive film and the position of the intersection K of the pair of central axes C1 and C2 of the plurality of non-conductive portions in the second transparent conductive film matched with each other in a plan view.

### Comparative Example 2

A light control device according to Comparative Example 2 was prepared using the same method as that of Example 8, except that the shape of the plurality of non-conductive portions of the first transparent conductive film and the shape of the plurality of non-conductive portions of the second transparent conductive film were changed to a cross shape shown in FIG. 5 not including the projection portions G1 and G2. In Comparative Example 2, the position of the intersection K of the pair of central axes C1 and C2 of the plurality of non-conductive portions in the first transparent conductive film and the position of the intersection K of the pair of central axes C1 and C2 of the plurality of non-conductive portions in the second transparent conductive film matched with each other in a plan view.

Regarding the transparent conductive films according to Examples 1 to 4 and Comparative Example 1 obtained as described above, deterioration evaluation and millimeter wave transmission evaluation described below were performed. Regarding the light control devices according to Examples 5 to 8 and Comparative Example 2, the millimeter wave transmission evaluation and shielding property evaluation described below were performed.

### (Deterioration Evaluation)

First, a conductive tape was bonded to the entire region of each of the pair of electrode pads of the transparent conductive films according to Examples 1 to 4 and Comparative Example 1 to measure a resistance value R1 between the conductive tapes. Next, the transparent conductive film was fixed such that the conductive film was orthogonal to a horizontal surface. In this case, any obstacle was not disposed in a range of 150 mm on opposite surfaces of the conductive film. Next, a crocodile clip connected to a power supply device (DME 1600 manufactured by Kikusui Electronics Corporation; a digital multimeter) was attached to each of the conductive tapes attached to the pair of electrode pads. By bonding two conductive tapes to the same electrode pad in advance such that the two conductive tapes did not come into contact with each other to measure resistances thereof, a contact resistance was measured through the electrode pad. It was verified that the contact resistance was 0.05Ω or less which was sufficiently ignorable with respect to the resistance value R1.

Next, the transparent conductive film was disposed in a constant-temperature tank set to conditions of temperature: 25° C., relative humidity: 60%, and a windless environment, and a voltage was continuously applied to the conductive film using the power supply device for 2000 hours while keeping the temperature of the conductive film at 100° C. In this case, the temperature of the conductive film was measured using a thermometer (ETS320 manufactured by FLIR). 2000 hours after applying a voltage to the conductive film, a resistance value R2 between the conductive tapes attached to the pair of electrode pads was measured, and a deterioration factor R2/R1 was calculated based on a ratio of the resistance value R2 to the resistance value R1.

Finally, the transparent conductive film was evaluated as AA to D below based on a value of a deterioration factor R2/R1. The evaluation AA represents that deterioration was not substantially observed. The evaluation A represents that deterioration was extremely suppressed. The evaluation B represents that deterioration was sufficiently suppressed. The evaluation C represents that deterioration was suppressed to some extent that there was no problem in practice. The evaluation D represents that clear deterioration occurred.
AA: the deterioration factor R2/R1 was 1.05 or less
A: the deterioration factor R2/R1 was more than 1.05 and 1.10 or less
B: the deterioration factor R2/R1 was more than 1.10 and 1.15 or less
C: the deterioration factor R2/R1 was more than 1.15 and 1.20 or less
D: the deterioration factor R2/R1 was more than 1.20

### (Millimeter Wave Transmission Evaluation)

The transmittance of the transparent conductive film according to each of Examples 1 to 4 and Comparative Example 1 with respect to a millimeter wave in a specific wavelength was measured using a millimeter wave network analyzer (N5290A, manufactured by Keysight Technologies Inc.). In this case, first, the transparent conductive film was bonded to a stainless steel plate having a thickness of 2 mm having a hole with a diameter of 80 mm. In addition, the millimeter wave network analyzer was provided such that two ports faced each other. In addition, the transparent conductive film bonded to the stainless steel plate was disposed such that the hole having a diameter of 80 mm of the stainless steel plate was positioned at an intermediate point between the two ports and the flat surface of the transparent conductive film was perpendicular to a line segment connecting the two ports. In this state, the transmittance of the transparent conductive film with respect to a millimeter wave in 76.5 GHz was measured. Assuming that the transmittance measured without disposing the transparent conductive film between the two ports was 0 dB, the transmittance of the transparent conductive film was calculated. A case where the measured transmittance was-1.0 dB or more was evaluated as A, and a case where the measured transmittance was less than-1.0 dB was evaluated as B. The evaluation B has no problem in practice but is poorer than the evaluation A.

The millimeter wave transmission evaluation regarding the light control devices according to Examples 5 to 8 and Comparative Example 2 was performed using the same method as that of the millimeter wave transmission evaluation regarding the transparent conductive films according to Examples 1 to 4 and Comparative Example 1. A case where the measured transmittance was-5.0 dB or more was evaluated as A, and a case where the measured transmittance was less than-5.0 dB was evaluated as B.

### (Shielding Property Evaluation)

10 observers were disposed at a position at a distance of 3 m from the light control devices according to each of Examples 5 to 8 and Comparative Example 2, and a still photograph was disposed at a position at a distance of 30 cm from the light control device on the side opposite to the side where the observers were disposed. In a room having an illuminance of 100 1× (lux), the energized state of the light control layer in the light control device was controlled such that the light control layer was in an opaque state. Next, each of the observers checked the light control device to evaluate whether or not the still photograph was visible through the light control device. A case where the number of persons who recognized the still photograph through the light control device was less than 2 was evaluated as A, a case where the number of persons was 2 or more and less than 5 was evaluated as B, and a case where the number of persons was 5 or more was evaluated as C. The evaluation A represents that the still photograph is not substantially visible through the light control device, that is, the light control device has excellent shielding properties. The evaluation B represents that the light control device has shielding properties that have no problem in practice. The evaluation C represents that the light control device has shielding properties that have a problem in practice.

Table 1 below shows the results of the deterioration evaluation and the millimeter wave transmission evaluation for Examples 1 to 4 and Comparative Example 1. In Table 1, the ratio of the area where the non-conductive portion occupies the unit region R is shown as “Area Ratio”, the gap A between the non-conductive portions will be simply shown as “Gap A”, and the radius B of the circumscribed circle of the non-conductive portion will be simply shown as “Radius B”.

TABLE 1

| | Area | Area of | | | | | | Millimeter |
|---|---|---|---|---|---|---|---|---|
| | of Unit | Non-Conductive | | Gap | Radius | | | Wave |
| | Region | Portion | Area | A | B | | Deterioration | Transmission |
| | (mm²) | (mm²) | Ratio | (mm) | (mm) | (A/2)/B | Evaluation | Evaluation |
| Example 1 | 2.82 | 0.88 | 31% | 0.56 | 0.66 | 0.42 | A | A |
| Example 2 | 2.82 | 0.79 | 28% | 0.48 | 0.66 | 0.36 | B | A |
| Example 3 | 2.82 | 0.56 | 20% | 0.37 | 0.68 | 0.27 | C | B |
| Example 4 | 2.82 | 0.88 | 31% | 0.56 | 0.63 | 0.44 | AA | A |
| Comparative | 2.82 | 0.71 | 25% | 0.28 | 0.705 | 0.20 | D | A |
| Example 1 | | | | | | | | |

As shown in Table 1, it can be seen that, in the transparent conductive films according to Examples 1 to 4, the results of the deterioration evaluation were all C or higher, and the function of allowing transmission of the millimeter wave was provided and the deterioration of the conductive wiring was not likely to occur even in a case where the mesh-shaped portion was energized. In the transparent conductive films according to Examples 1 to 4, the non-conductive portions include the projection portions. Therefore, it is considered that while ensuring the length of the arm for allowing an electromagnetic wave in a desired frequency band to transmit through the non-conductive portion, the dimensions of the non-conductive portion in the X direction and the Y direction can be reduced, and local concentration of a current between the non-conductive portions can be suppressed.

On the other hand, the result of the deterioration evaluation of Comparative Example 1 was D. In Comparative Example 1, the non-conductive portions had the simple cross shape. Therefore, in order to allow the millimeter wave to transmit through the non-conductive portion, the length L6 of the pair of extension portions needs to be set to be longer than that of the non-conductive portions according to Examples 1 to 4. Therefore, in Comparative Example 1, the gap A between the non-conductive portions is short at 0.28, the value of (A/2)/B is small at 0.20, and local concentration of a current between the non-conductive portions is likely to occur.

Here, in the deterioration evaluation, the result of Example 1 was A, the result of Example 2 was B, the result of Example 3 was B, and the result of Example 4 was AA. Focusing on the values of (A/2)/B of Examples 1 to 4, the values were 0.42, 0.36, 0.27, and 0.44, respectively. This way, it can be seen that, in order of Examples 4, 1, 2, and 3, the gap A between the non-conductive portions with respect to the size of the non-conductive portion decreased, and local concentration of a current between the non-conductive portions was more likely to occur. However, in all of Examples 1 to 4, (A/2)/B>0.2 was satisfied, and local concentration of a current between the non-conductive portions was suppressed.

In addition, the results of the millimeter wave transmission evaluation of Examples 1, 2, and 4 and Comparative Example 1 were A, and the result of the millimeter wave transmission evaluation of Example 3 was B. The reason for this is presumed to be that, since the ratio of the area where the non-conductive portion occupied the unit region R was small at 20%, the amount of the millimeter wave transmitted through the non-conductive portion was small. It can be seen from the results shown in Table 1 that, in a case where the ratio of the area where the non-conductive portion occupied the unit region R is 25% or more, the non-conductive portion has excellent transmittance with respect to the millimeter wave.

Table 2 below shows the results of the shielding property evaluation and the millimeter wave transmission evaluation for Examples 5 to 8 and Comparative Example 2.

TABLE 2

| | Extension Portion | | Maximum | Width of | | Millimeter |
|---|---|---|---|---|---|---|
| | of | Material for | Amount of | Extension | Shielding | Wave |
| | Non-Conductive | Forming Light | Shift | Portion/Amount | Property | Transmission |
| | Portion | Control Layer | (mm) | of Shift | Evaluation | Evaluation |
| Example 5 | Provided | Electrochromic | 0.000 | 0.00 | A | A |
| Example 6 | Provided | Electrochromic | 0.066 | 0.20 | A | A |
| Example 7 | Provided | Electrochromic | 0.092 | 0.28 | A | B |
| Example 8 | Provided | Liquid Crystal | 0.000 | 0.00 | B | A |
| Comparative | Not Provided | Liquid Crystal | 0.000 | 0.00 | C | A |
| Example 2 | | | | | | |

As shown in Table 2, it can be seen that, in the light control devices according to Examples 5 to 8, all of the results of the shielding property evaluation were B or higher, and the function of allowing transmission of the millimeter wave was provided and the visual recognition of the still photograph by the observers through the light control device was suppressed even in a case where the light control layer was in an opaque state. In Examples 5 to 8, the non-conductive portions include the projection portions. Therefore, it is considered that, while ensuring the length of the arm for allowing an electromagnetic wave in a desired frequency band to transmit through the non-conductive portion, the dimensions of the non-conductive portion in the X direction and the Y direction can be reduced, slits in a lattice form that are regularly arranged are not likely to be formed, and the recognition of a scene through the light control device is suppressed.

On the other hand, the result of the shielding property evaluation of Comparative Example 2 was C. In Comparative Example 2, the non-conductive portions had the simple cross shape. Therefore, in order to allow the millimeter wave to transmit through the non-conductive portion, the length L6 of the pair of extension portions needs to be set to be longer than that of the non-conductive portions according to Examples 5 to 8. Therefore, in Comparative Example 2, it is considered that slits in a lattice form that were regularly arranged were formed by the plurality of non-conductive portions, and the observers were likely to recognize a scene on the opposite side of the light control device through the slits.

Here, regarding the shielding property evaluation, the results of Examples 5 to 7 were A, and the result of Example 8 was B. In Example 5 to 7, an electrochromic material was used as a material for forming the light control layer. In Example 8, a liquid crystal material was used as a material for forming the light control layer. Therefore, it is considered that, in Examples 5 to 7, the color of the electrochromic layer bled out to the non-conductive portions such that shielding properties were improved.

Here, regarding the millimeter wave transmission evaluation, the results of Examples 5 and 6 were A, and the result of Example 7 was B. Focusing on the values of the width of the extension portion/the maximum amount of shift of Examples 5 to 7, the values were 0.00, 0.20, and 0.28, respectively. This way, it can be seen that, as the maximum amount of shift of the non-conductive portions of the first transparent conductive film and the non-conductive portions of the second transparent conductive film in a plan view with respect to the width of the extension portion decreases, the shape of the region N where non-conductive portions of the first transparent conductive film and the shape of the plurality of non-conductive portions of the second transparent conductive film overlap each other approaches the shape of the non-conductive portions of the first transparent conductive film and the non-conductive portions of the second transparent conductive film, and the transmission of the electromagnetic wave in the specific frequency band is likely to be selectively allowed. In particular, it can be seen that, by setting the value of the width of the extension portion/the maximum amount of shift to be about 0.25 or less, the shape of the region N can be made to approach the shape of the non-conductive portions of the first transparent conductive film and the non-conductive portions of the second transparent conductive film, and excellent millimeter wave transmittance can be obtained.

Basically, the present invention is configured as described above. Hereinabove, the transparent conductive film and the light control device according to the embodiment of the present invention have been described in detail. However, the present invention is not limited to the above-described examples, and various improvements or modifications can be made within a range not departing from the scope of the present invention.

### EXPLANATION OF REFERENCES

11: transparent conductive film
12: substrate
12A: first substrate
12B: second substrate
13: conductive layer
13A: first conductive layer
13B: second conductive layer
14: mesh-shaped portion
15: electrode pad
21, 21A: conductive wiring
22 to 25, 22A, 22B, 32: non-conductive portion
41: light control layer
42: transparent auxiliary conductive layer
A, M1, M2: gap
B: Radius
C1, C2, C1A, C1B, C2A, C2B: central axis
CL: center line
E1, E2: extension portion
F: circumscribed circle
G1, G2: projection portion
H: opening portion
J: interior angle
K: intersection
L1, L6, L8, L11,L15, L19: length
L2, L3, L7, L9, L12 to L14, L16, L17: width
L4, L18: thickness
L5: length of arm
L10: maximum width
N: region
P: arrangement pitch
Q: pitch
R: unit region
T: line width

What is claimed is:

1. A transparent conductive film for a heater, the transparent conductive film comprising:
a substrate; and
a mesh-shaped portion that is disposed on the substrate and is formed of a plurality of conductive wirings,
wherein the mesh-shaped portion includes a plurality of non-conductive portions that are arranged to form a regular repeating pattern and are trimmed by the continuous conductive wiring,
the non-conductive portion includes a pair of extension portions that extend along a pair of central axes orthogonal to each other and have the same length,
the pair of extension portions intersect each other at an intersection of the pair of central axes,
each of the pair of extension portions includes a projection portion that projects in a direction intersecting an extension direction, and
the non-conductive portion has a shape that is symmetric with respect to each of the pair of central axes.

2. The transparent conductive film for a heater according to claim 1,
wherein a gap A between the non-conductive portions adjacent to each other and a radius B of a circumscribed circle of the non-conductive portion satisfy
(A/2)/B>0.2.

3. The transparent conductive film for a heater according to claim 1,
wherein the repeating pattern is configured such that a plurality of square unit regions each of which surrounds the non-conductive portion centering on the intersection of the pair of central axes in the non-conductive portion are arranged in a direction along the pair of central axes, and
a ratio of an area in which the non-conductive portion occupies the unit region is 25% or more and 50% or less.

4. The transparent conductive film for a heater according to claim 2,
wherein the repeating pattern is configured such that a plurality of square unit regions each of which surrounds the non-conductive portion centering on the intersection of the pair of central axes in the non-conductive portion are arranged in a direction along the pair of central axes, and
a ratio of an area in which the non-conductive portion occupies the unit region is 25% or more and 50% or less.

5. The transparent conductive film for a heater according to claim 1,
wherein a conductive member is not present inside the continuous conductive wiring that trims the non-conductive portion.

6. The transparent conductive film for a heater according to claim 2,
wherein a conductive member is not present inside the continuous conductive wiring that trims the non-conductive portion.

7. The transparent conductive film for a heater according to claim 3,
wherein a conductive member is not present inside the continuous conductive wiring that trims the non-conductive portion.

8. The transparent conductive film for a heater according to claim 1,
wherein the projection portions adjacent to each other in the non-conductive portion are disposed at a gap.

9. The transparent conductive film for a heater according to claim 2,
wherein the projection portions adjacent to each other in the non-conductive portion are disposed at a gap.

10. The transparent conductive film for a heater according to claim 3,
wherein the projection portions adjacent to each other in the non-conductive portion are disposed at a gap.

11. The transparent conductive film for a heater according to claim 1,
wherein the continuous conductive wiring that trims the non-conductive portion consists of two kinds of linear portions parallel to the pair of central axes, respectively.

12. A transparent conductive film for a light control device, the transparent conductive film comprising:
a substrate; and
a mesh-shaped portion that is disposed on the substrate and is formed of a plurality of conductive wirings,
wherein the mesh-shaped portion includes a plurality of non-conductive portions that are arranged to form a regular repeating pattern and are trimmed by the continuous conductive wiring,
the non-conductive portion includes a pair of extension portions that extend along a pair of central axes orthogonal to each other and have the same length,
the pair of extension portions intersect each other at an intersection of the pair of central axes,
each of the pair of extension portions includes a projection portion that projects in a direction intersecting an extension direction, and
the non-conductive portion has a shape that is symmetric with respect to each of the pair of central axes.

13. A light control device comprising:
a pair of the transparent conductive films for a light control device according to claim 12 that are disposed such that the mesh-shaped portions face each other; and
a light control layer that is disposed between the pair of transparent conductive films for a light control device and where optical characteristics change depending on an electric signal.

14. The light control device according to claim 13,
wherein the projection portions adjacent to each other in the non-conductive portion are disposed at a gap.

15. The light control device according to claim 13,
wherein at least one non-conductive portion among the plurality of non-conductive portions in one transparent conductive film for a light control device among the pair of transparent conductive films for a light control device and the non-conductive portion in the other transparent conductive film for a light control device corresponding to the at least one non-conductive portion are disposed to be shifted from each other in a plan view, and
a maximum amount of shift of the at least one non-conductive portion and the corresponding non-conductive portion in the plan view is 0.25 times or less a width of the extension portion.

16. The light control device according to claim 13,
wherein a position of the intersection of the pair of central axes of the plurality of non-conductive portions in one transparent conductive film for a light control device among the pair of transparent conductive films for a light control device and a position of the intersection of the pair of central axes of the plurality of non-conductive portions in the other transparent conductive film for a light control device match with each other in a plan view.

17. The light control device according to claim 13,
wherein a conductive member is not present inside the continuous conductive wiring that trims the non-conductive portion.

18. The light control device according to claim 13,
wherein the continuous conductive wiring that trims the non-conductive portion consists of two kinds of linear portions parallel to the pair of central axes, respectively.

19. The light control device according to claim 13,
wherein the mesh-shaped portion includes a conductive transparent auxiliary conductive layer that is disposed in a region other than the non-conductive portion.

20. The light control device according to claim 13,
wherein the light control layer is a liquid crystal layer or an electrochromic layer.
